(19) United States
(12) Patent Application Publication
(10) Pub. No.: US 2025/0299918 A1
(43) Pub. Date: Sep. 25, 2025

(54) POSITION MEASUREMENT APPARATUS, CHARGED PARTICLE BEAM WRITING APPARATUS, AND MARK POSITION MEASUREMENT METHOD

(71) Applicant: NuFlare Technology, Inc., Yokohama-shi (JP)

(72) Inventors: Hiroshi SATO, Utsunomiya-shi (JP); Yuto ASAKURA, Yokohama-shi (JP)

(73) Assignee: NuFlare Technology, Inc., Yokohama-shi (JP)

(21) Appl. No.: 19/228,999

(22) Filed: Jun. 5, 2025

Related U.S. Application Data
(63) Continuation of application No. PCT/JP2023/040787, filed on Nov. 13, 2023.

(30) Foreign Application Priority Data
Dec. 9, 2022 (JP) 2022-197368

(51) Int. Cl. H01J 37/304; G03F 9/00; H01J 37/04; H01J 37/317

(52) U.S. Cl. CPC H01J 37/3045; G03F 9/7084; G03F 9/7088; H01J 37/045; H01J 37/3177; H01J 2237/0437; H01J 2237/24578; H01J 2237/30483

(57) ABSTRACT

According to one aspect of the present invention, a position measurement apparatus, includes a movable stage, a target object having an uneven mark with a concave surface and a convex surface formed of a same material being placed on the stage; and a position calculation circuit configured to calculate a position of the uneven mark using a height position distribution of the surface of the target object as the height information of the surface of the target object, the height position distribution of the surface of the target object being obtained by performing a scan with the laser light so as to cross the uneven mark and generated by a relative positional relationship between the predetermined light intensity distribution and the uneven mark.

### CROSS-REFERENCE TO RELATED APPLICATION

This application is a continuation application based upon and claims the benefit of priority from prior Japanese Patent Application No. 2022-197368 (application number) filed on Dec. 9, 2022 in Japan, and International Application PCT/JP2023/040787, the International Filing Date of which is Nov. 13, 2023. The contents described in JP2022-197368 and PCT/JP2023/040787 are incorporated herein by reference.

### BACKGROUND OF THE INVENTION

### Field of the Invention

One aspect of the present invention relates to a position measurement apparatus, a charged particle beam writing (or “drawing”) apparatus, and a mark position measurement method, and relates to, for example, a method for measuring the position of an alignment mark on a drawing target object.

### Related Art

Lithography technology, which is responsible for the advancement of miniaturization of semiconductor devices, is an extremely important process that is the only pattern generation process among the semiconductor manufacturing processes. In recent years, as LSIs have become more highly integrated, the circuit line width required for semiconductor devices has become smaller year by year. Here, electron beam writing technology is basically excellent in terms of resolution, and accordingly writing is performed on wafers and the like using an electron beam.

For example, there is a writing apparatus using multiple beams. Compared to the case of writing using a single electron beam, using multiple beams allows irradiation using a large amount of beams at a time, resulting in a significant improvement in throughput. In such a writing apparatus based on the multi-beam method, for example, electron beams emitted from an electron emission source pass through a mask having a plurality of holes to form multiple beams, and each of the multiple beams is subjected to blanking control so that each beam that is not blocked is demagnified by an optical system, deflected by a deflector, and emitted to a desired position on a target object.

In electron beam writing including multi-beam writing, when arranging a writing target substrate on a stage, an alignment mark formed on the substrate is detected by an electron beam. Then, the position of the writing region is aligned with the detected alignment mark as a reference.

In electron beam writing, the writing position on the mask may be specified with high accuracy to perform writing. For example, in the case of a phase shift mask, when creating a mask with a plurality of layers, it is necessary to align the relative positions of the patterns of the first and second layers. In order to influence the writing performance in lithography using this mask, it is necessary to create the relative positions of the patterns between the layers with high accuracy of about several nm.

In addition, for EUV masks, a substrate that has been inspected for defects in advance is used, and patterns are written while avoiding the coordinates of the defects.

Therefore, a mark provided on a mask substrate is measured, and the mark is used as a reference for alignment and writing, thereby specifying the writing position with high accuracy.

A modern alignment mark is formed with a smaller pattern linewidth than conventional alignment marks. In addition, a mark may be formed with an uneven structure of the same material. In this case, the electron yield when the mark is irradiated with an electron beam is small, making it difficult to obtain contrast. As a result, there has been a problem that the S/N ratio is poor and it is difficult to find the alignment mark on the substrate. As a countermeasure to this problem, it is considered to increase the exposure intensity of the electron beam in order to obtain contrast. However, this method has a problem in that the resist is irradiated with a high exposure intensity of electron beam over a wide range, causing the resist to scatter and contaminate the inside of the chamber.

Here, a mark, which is formed of materials with different reflectances for laser light and has a size larger than the beam diameter of the laser light, is scanned with the laser light to detect the reflected light. Then, a method is disclosed in which a mark position is determined from a change in the center of gravity of the detected reflected light that occurs at the boundary between the materials (see Published Unexamined Japanese Patent Application No. 2010-267758, for example). In this method, however, it is difficult to detect a mark formed with a pattern linewidth smaller than the beam diameter of the laser light. In addition, since the reflectance of a mark formed with an uneven structure of the same material is unlikely to change, it is difficult to detect such a mark.

### BRIEF SUMMARY OF THE INVENTION

According to one aspect of the present invention, a position measurement apparatus, includes:
a movable stage, a target object having an uneven mark with a concave surface and a convex surface formed of a same material being placed on the stage;
a sensor having a light projector for making laser light obliquely incident on a surface of the target object and a light receiver for receiving reflected light from the target object due to emission of the laser light and outputting height information of the surface of the target object, the laser light having a predetermined light intensity distribution and having a diameter larger than a width of the uneven mark; and
a position calculation circuit configured to calculate a position of the uneven mark using a height position distribution of the surface of the target object as the height information of the surface of the target object, the height position distribution of the surface of the target object being obtained by performing a scan with the laser light so as to cross the uneven mark and generated by a relative positional relationship between the predetermined light intensity distribution and the uneven mark.

According to another aspect of the present invention, a charged particle beam writing apparatus, includes:
a position measurement apparatus above-mentioned; and
a writing mechanism configured to write a pattern on the target object on the stage using a charged particle beam.

According to further another aspect of the present invention, a mark position measurement method, includes:
searching for a position of an uneven mark on a surface of a target object placed on a stage and having the uneven mark with a concave surface and a convex surface formed of a same material by calculating the position of the uneven mark using a height position distribution of the surface of the target object as height information of the surface of the target object, the height position distribution of the surface of the target object being obtained by performing a scan with laser light so as to cross the uneven mark using a sensor having a light projector for making the laser light having a predetermined light intensity distribution and having a diameter larger than a width of the uneven mark obliquely incident on the surface of the target object and a light receiver for receiving reflected light from the target object due to emission of the laser light and outputting the height information of the surface of the target object while moving the target object and generated by a relative positional relationship between the predetermined light intensity distribution and the uneven mark; and
measuring the position of the uneven mark by scanning the uneven mark with an electron beam after moving the stage to a position where the uneven mark is irradiated with the electron beam using information on a searched position of the uneven mark.

### BRIEF DESCRIPTION OF THE DRAWINGS

FIG. 1 is a conceptual diagram showing the configuration of a writing apparatus according to Embodiment 1;

FIG. 2 is a conceptual diagram showing the configuration of a shaping aperture array substrate in Embodiment 1;

FIG. 3 is a cross-sectional view showing the configuration of a blanking aperture array mechanism in Embodiment 1;

FIG. 4 is a top view showing an example of the configuration of a target object according to Embodiment 1;

FIG. 5 is a cross-sectional view showing an example of the configuration of an alignment mark in Embodiment 1;

FIG. 6 is a cross-sectional view showing another example of the configuration of the alignment mark in Embodiment 1;

FIG. 7 is a flowchart showing an example of main steps of a writing method according to Embodiment 1;

FIG. 8 is a diagram for explaining a method of performing a mark rough search in Embodiment 1;

FIG. 9 is a diagram for explaining the measurement principle of a z sensor in Embodiment 1;

FIG. 10 is a diagram showing an example of the intensity distribution of laser light used in the z sensor in Embodiment 1;

FIG. 11 is a cross-sectional view showing an example of a state of emitted light when an alignment mark is scanned by the z sensor in Embodiment 1;

FIG. 12 is a cross-sectional view showing an example of a state of reflected light when an alignment mark is scanned by the z sensor in Embodiment 1;

FIG. 13 is a diagram showing an example of the height position distribution of an uneven mark in Embodiment 1;

FIG. 14 is a diagram showing an example of the height position distribution in Embodiment 1;

FIG. 15 is a diagram showing an example of the intensity distribution of laser light in a comparative example of Embodiment 1;

FIG. 16 is a diagram showing an example of the height position distribution of an uneven mark in a comparative example of Embodiment 1;

FIG. 17 is a diagram for explaining the relationship among the incidence angle of laser light, the step of an uneven mark, and the width of the uneven mark in Embodiment 1;

FIG. 18 is a diagram showing the relationship between the step of the uneven mark and 2d·tan θ in Embodiment 1;

FIG. 19 is a conceptual diagram for explaining an example of a writing operation in Embodiment 1;

FIG. 20 is a diagram showing an example of a multi-beam irradiation region and a writing target pixel in Embodiment 1;

FIG. 21 is a diagram for explaining an example of a multi-beam writing operation in Embodiment 1;

FIG. 22 is a conceptual diagram showing the configuration of a writing apparatus according to Embodiment 2; and

FIG. 23 is a diagram showing an example of the height position distribution in a comparative example of Embodiment 2.

### DETAILED DESCRIPTION OF THE INVENTION

In the following embodiments, an apparatus and a method are provided that can detect a mark, which has a size smaller than the beam diameter of an emitted beam and has a surface formed of the same material, while suppressing the scattering of a resist.

In the following embodiments, a configuration using an electron beam as an example of a charged particle beam will be described. However, the charged particle beam is not limited to an electron beam, and may be a beam using a charged particle such as an ion beam. In addition, although a writing apparatus using multiple beams will be described below, the invention is not limited to this. A writing apparatus using a single beam may also be used. For example, the invention can be applied to a variable shaped beam (VSB) type writing apparatus.

### EMBODIMENT 1

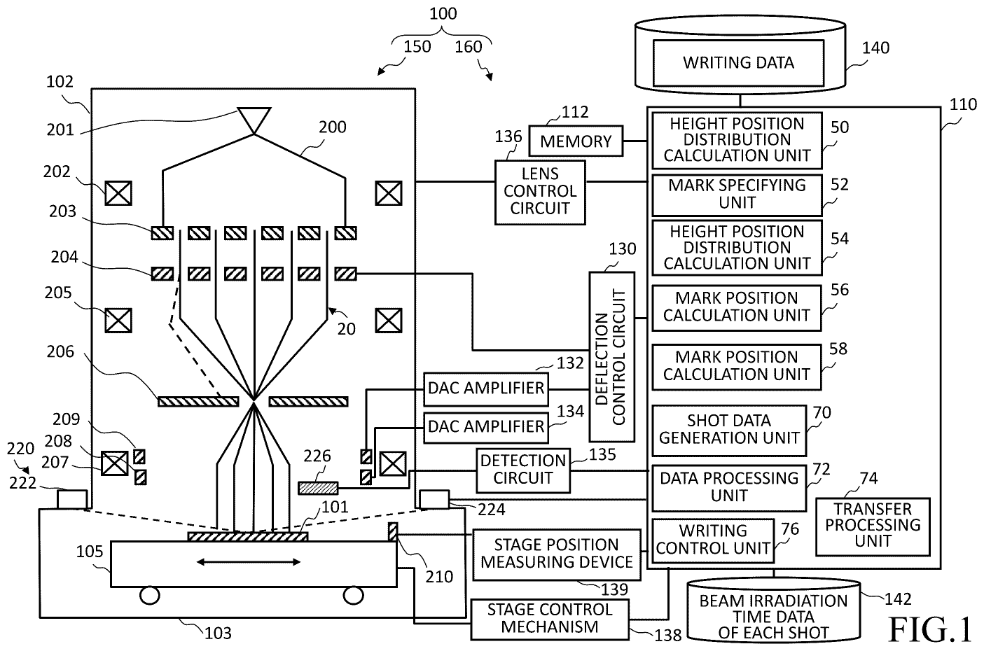

FIG. 1 is a conceptual diagram showing the configuration of a writing apparatus according to Embodiment 1. In FIG. 1, a writing apparatus 100 includes a writing mechanism 150 and a control system circuit 160. The writing apparatus 100 is an example of a multi-charged particle beam writing apparatus and an example of a multi-charged particle beam exposure apparatus. The writing mechanism 150 includes an electron optical column 102 (electron beam column) and a writing chamber 103. An electron emission source 201, an illumination lens 202, a shaping aperture array substrate 203, a blanking aperture array mechanism 204, a demagnifying lens 205, a limiting aperture substrate 206, an objective lens 207, a deflector 208, a deflector 209, and a detector 226 are arranged inside the electron optical column 102.

An XY stage 105 is arranged in the writing chamber 103. On the XY stage 105, a target object 101 such as a mask, which becomes a writing target substrate during writing (during exposure), is arranged. The target object 101 includes an exposure mask used in manufacturing semiconductor devices, a semiconductor substrate (silicon wafer) on which a semiconductor device is manufactured, and the like. In addition, the target object 101 includes a mask blank which is coated with resist and on which nothing has been written yet. An alignment mark, which will be described later, is formed on the target object 101.

In addition, a mirror 210 for measuring the position of an XY stage 105 is further arranged on the XY stage 105.

In addition, a z sensor 220 (an example of a sensor) is arranged on a writing chamber 103. The z sensor 220 has a light projector 222 that emits, for example, visible laser light and a light receiver 224 that receives reflected light from an object due to the emission of the laser light.

The light projector 222 makes laser light obliquely incident on the surface of the target object 101 arranged on the XY stage 105 in the writing chamber 103. The laser light projected from the light projector 222 has a light intensity distribution of a normal distribution. In addition, the laser light projected from the light projector 222 has a diameter larger than the width of an alignment mark formed on the target object 101. This is due to the diameter of the light beam at the time of emission and optical elements that guide the light, and is also largely due to the influence of the light spreading in the direction of incidence due to oblique incidence on the target object. For example, laser light having a diameter of 10 to 300 μm on the surface of the target object 101 is used. For example, laser light having a diameter of about 200 μm on the surface of the target object 101 is preferably used.

The light receiver 224 receives the reflected light from the target object 101 due to the emission of the laser light, and outputs height information of the surface of the target object 101. As the light receiver 224, for example, a light position sensor is used. The light receiver 224 receives the reflected light, measures the height position of the surface of the target object 101 from the deviation of the light receiving position on the light receiving surface, and outputs the measured height position.

A control system circuit 160 includes a control calculator 110, a memory 112, a deflection control circuit 130, digital-to-analog conversion (DAC) amplifier units 132 and 134, a detection circuit 135, a lens control circuit 136, a stage control mechanism 138, a stage position measuring device 139, and storage devices 140 and 142 such as a magnetic disk device. The control calculator 110, the memory 112, the deflection control circuit 130, the detection circuit 135, the lens control circuit 136, the stage control mechanism 138, the stage position measuring device 139, and the storage devices 140 and 142 are connected to each other through a bus (not shown). The DAC amplifiers 132 and 134 and the blanking aperture array mechanism 204 are connected to the deflection control circuit 130. The deflector 209 is formed by electrodes having four or more poles, and each electrode is controlled by the deflection control circuit 130 through the DAC amplifier 132. The deflector 208 is formed by electrodes having four or more poles, and each electrode is controlled by the deflection control circuit 130 through the DAC amplifier 134. For example, a group of electromagnetic lenses such as an illumination lens 202, a demagnifying lens 205, and an objective lens 207 are controlled by the lens control circuit 136. A detector 226 is connected to the detection circuit 135.

The position of the XY stage 105 is controlled by driving motors for each axis (not shown) controlled by the stage control mechanism 138. The stage position measuring device 139 measures the position of the XY stage 105 using the principle of laser interferometry by receiving the reflected light from the mirror 210.

The control calculator 110 includes a height position distribution calculation unit 50, a mark specifying unit 52, a height position distribution calculation unit 54, a mark position calculation unit 56, a mark position calculation unit 58, a shot data generation unit 70, a data processing unit 72, a transfer processing unit 74, and a writing control unit 76. Each “˜unit”, such as the height position distribution calculation unit 50, the mark specifying unit 52, the height position distribution calculation unit 54, the mark position calculation unit 56, the mark position calculation unit 58, the shot data generation unit 70, the data processing unit 72, the transfer processing unit 74, and the writing control unit 76, has a processing circuit. Examples of such a processing circuit include an electrical circuit, a computer, a processor, a circuit board, a quantum circuit, or a semiconductor device. For each “˜unit”, a common processing circuit (the same processing circuit) may be used or different processing circuits (separate processing circuits) may be used. Information input and output to and from the height position distribution calculation unit 50, the mark specifying unit 52, the height position distribution calculation unit 54, the mark position calculation unit 56, the mark position calculation unit 58, the shot data generation unit 70, the data processing unit 72, the transfer processing unit 74, and the writing control unit 76 and information being calculated are stored in the memory 112 each time.

The XY stage 105, the z sensor 220, the deflector 209, the detector 226, the detection circuit 135, the height position distribution calculation unit 50, the mark specifying unit 52, the height position distribution calculation unit 54, the mark position calculation unit 56, the mark position calculation unit 58, and the like are used not only as components of a writing apparatus 100, but also as components of a position measurement apparatus according to Embodiment 1.

The writing operation of the writing apparatus 100 is controlled by the writing control unit 76. In addition, processing for the transfer of beam irradiation time data of each shot to the deflection control circuit 130 is controlled by the transfer processing unit 74.

In addition, writing data (chip data) is input from outside the writing apparatus 100 and is stored in the storage device 140. The chip data defines information of a plurality of figures forming a chip pattern. Specifically, for example, a figure code, coordinates, size, and the like are defined for each figure.

Here, FIG. 1 describes components necessary for explaining Embodiment 1. The writing apparatus 100 may also include other components that are normally required.

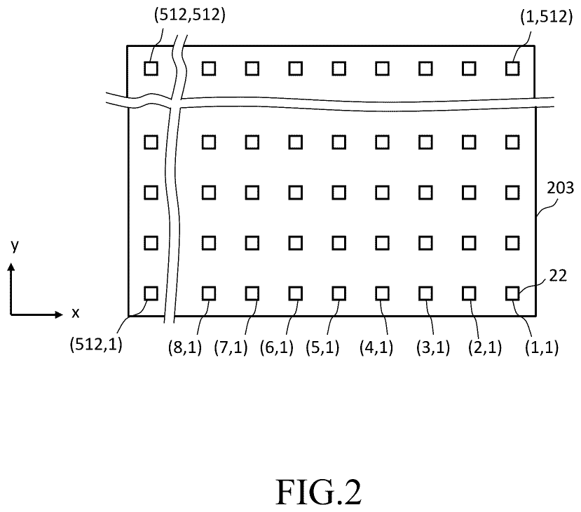

FIG. 2 is a conceptual diagram showing the configuration of a shaping aperture array substrate in Embodiment 1. In FIG. 2, in the shaping aperture array substrate 203, holes (openings) 22 are formed in a matrix of p columns long (in the y direction)×q rows wide (in the x direction) (p, q≥2) at predetermined arrangement pitches. In the example of FIG. 2, a case is shown in which, for example, 512×512 columns of holes 22 are formed in length and width directions (x and y directions). The number of holes 22 is not limited to thereto. For example, 32×32 columns of holes 22 may be formed. The holes 22 are formed in rectangles having the same dimension and shape. Alternatively, the holes 22 may be circles having the same diameter. Some of electron beams 200 pass through the plurality of holes 22 to form multiple beams 20. In other words, the shaping aperture array substrate 203 forms and emits multiple beams 20. The shaping aperture array substrate 203 is an example of an emission source for the multiple beams 20.

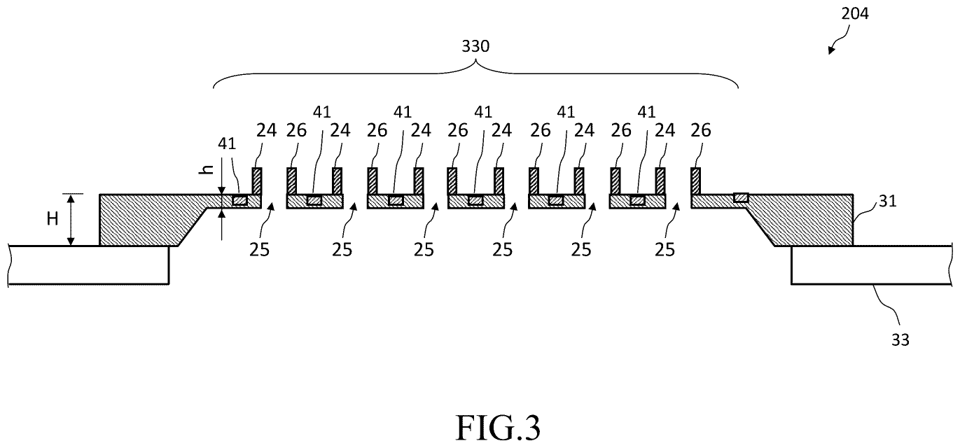

FIG. 3 is a cross-sectional view showing the configuration of a blanking aperture array mechanism in Embodiment 1. In the blanking aperture array mechanism 204, as shown in FIG. 3, a blanking aperture array substrate 31 using a semiconductor substrate formed of silicon or the like is arranged on a support base 33. In a membrane region 330 at the center of the blanking aperture array substrate 31, a through hole 25 (opening) through which each of the multiple beams 20 passes is opened at a position corresponding to each hole 22 of the shaping aperture array substrate 203 shown in FIG. 2. Then, a set of a control electrode 24 and a counter electrode 26 (blanker: blanking deflector) are arranged at positions facing each other with a corresponding passage hole 25 among the plurality of passage holes 25 interposed therebetween. In addition, a control circuit 41 (logic circuit) to apply a deflection voltage to the control electrode 24 for each through hole 25 is arranged inside the blanking aperture array substrate 31 near each through hole 25. The counter electrode 26 for each beam is grounded.

In the control circuit 41, an amplifier (an example of a switching circuit), which is not shown, is arranged. A CMOS (Complementary MOS) inverter circuit serving as a switching circuit is arranged as an example of the amplifier. Either an L (low) potential (for example, ground potential) that is lower than the threshold voltage or an H (high) potential (for example, 1.5 V) that is equal to or higher than the threshold voltage is applied to the input (IN) of the CMOS inverter circuit as a control signal. In Embodiment 1, in a state in which the L potential is applied to the input (IN) of the CMOS inverter circuit, the output (OUT) of the CMOS inverter circuit applied to the control circuit 41 has a positive potential (Vdd), and the corresponding beam is deflected by the electric field due to the potential difference from the ground potential of the counter electrode 26 and blocked by the limiting aperture substrate 206. In this manner, the beam is controlled to be turned off. On the other hand, in a state in which the H potential is applied to the input (IN) of the CMOS inverter circuit (active state), the output (OUT) of the CMOS inverter circuit has a ground potential, and there is no potential difference from the ground potential of the counter electrode 26. Therefore, since the corresponding beam is not deflected, the beam passes through the limiting aperture substrate 206. In this manner, the beam is controlled to be turned on. Blanking control is made by such deflection.

Next, a specific example of the operation of the writing mechanism 150 will be described. An electron beam 200 emitted from the electron emission source 201 (emission source) illuminates the entire shaping aperture array substrate 203 almost vertically through the illumination lens 202. A plurality of rectangular holes 22 (openings) are formed in the shaping aperture array substrate 203, and the electron beam 200 illuminates a region including all of the plurality of holes 22. Some of the electron beams 200 emitted to the positions of the plurality of holes 22 pass through the plurality of holes 22 in the shaping aperture array substrate 203 to form, for example, rectangular multiple beams (a plurality of electron beams) 20. Such multiple beams 20 pass through each corresponding blanker of the blanking aperture array mechanism 204. Each blanker performs blanking control on a beam passing therethrough individually so that the beam is in an ON state during the set writing time (beam irradiation time).

The multiple beams 20 that have passed through the blanking aperture array mechanism 204 are reduced by the demagnifying lens 205 and travel toward a central hole formed in the limiting aperture substrate 206. Here, the electron beam deflected by the blanker of the blanking aperture array mechanism 204 is displaced from the central hole of the limiting aperture substrate 206 and is blocked by the limiting aperture substrate 206. On the other hand, the electron beam that is not deflected by the blanker of the blanking aperture array mechanism 204 passes through the central hole of the limiting aperture substrate 206 as shown in FIG. 1. Thus, the limiting aperture substrate 206 blocks each beam that is deflected by the blanker of the blanking aperture array mechanism 204 so as to be in a beam OFF state. Then, by the beam that has passed through the limiting aperture substrate 206 and is formed from the beam ON state to the beam OFF state, each beam for one shot is formed. The multiple beams 20 that have passed through the limiting aperture substrate 206 are focused by the objective lens 207 to become a pattern image having a desired reduction ratio, and all of the multiple beams 20 that have passed through the limiting aperture substrate 206 are collectively deflected in the same direction by the deflector 208 and the deflector 209 and emitted to each irradiation position on the target object 101 of each beam. In addition, for example, when the XY stage 105 is continuously moving, tracking control is performed by the deflector 208 so that the irradiation position of the beam follows the movement of the XY stage 105. The multiple beams 20 emitted at one time are ideally arranged at a pitch obtained by multiplying the arrangement pitch of the plurality of holes 22 of the shaping aperture array substrate 203 by the desired reduction ratio described above.

Here, in electron beam writing including, for example, VSB type single beam writing, other than multi-beam writing, when arranging a writing target substrate on a stage, an alignment mark formed on the target object is detected. Then, the position of the writing region is aligned with the detected alignment mark as a reference. A modern alignment mark is formed with a smaller pattern linewidth than conventional alignment marks.

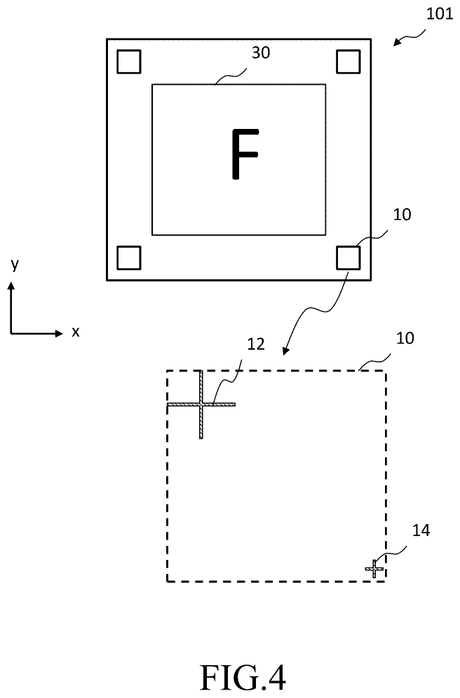

FIG. 4 is a top view showing an example of the configuration of a target object in Embodiment 1. In FIG. 4, on the target object 101, a writing region 30 for writing a desired pattern, which is located at the center, and an alignment mark region 10, which is located outside the writing region 30, for example, at each of the four corners of the target object 101, are set. In the example of FIG. 4, four alignment mark regions 10 are set. In each alignment mark region 10, a large mark 12 having a large mark size and a small mark 14 having a small mark size are formed.

In the example of FIG. 4, a case is shown in which the large mark 12 and the small mark 14 are formed at diagonal positions in the alignment mark region 10 of, for example, 11000 μm square. As both the large mark 12 and the small mark 14, for example, a cross pattern is used. Both the large mark 12 and the small mark 14 are formed as uneven marks each having an uneven structure in which a concave surface and a convex surface are formed of the same material. The cross pattern forms a concave portion, and the area around the cross pattern forms a convex portion. Therefore, such uneven marks are formed on the target object 101.

The large mark 12 is formed with a large mark size of about 4000 μm, and is used as a temporary alignment mark mainly for searching for the alignment mark region 10 from a wide region on the surface of the target object 101, for example. The small mark 14 is formed with a small mark size of about 400 μm, and is used as an alignment mark that serves as a position reference. The large mark 12 may be used as an alignment mark that serves as a position reference. In addition, the small mark 14 may be used to search for the alignment mark region 10 from a wide region on the surface of the target object 101.

As the large mark 12 and the small mark 14, for example, patterns with the same pattern linewidth are used. Both the large mark 12 and the small mark 14 are formed by a cross pattern obtained by combining a line pattern extending in the x direction with a pattern linewidth of 2 to 200 μm and a line pattern extending in the y direction with the same pattern linewidth as the line pattern extending in the x direction. Both the large mark 12 and the small mark 14 are formed so that the pattern linewidth of the concave portion is for example, 4 to 5 μm. The specific configuration will be described below.

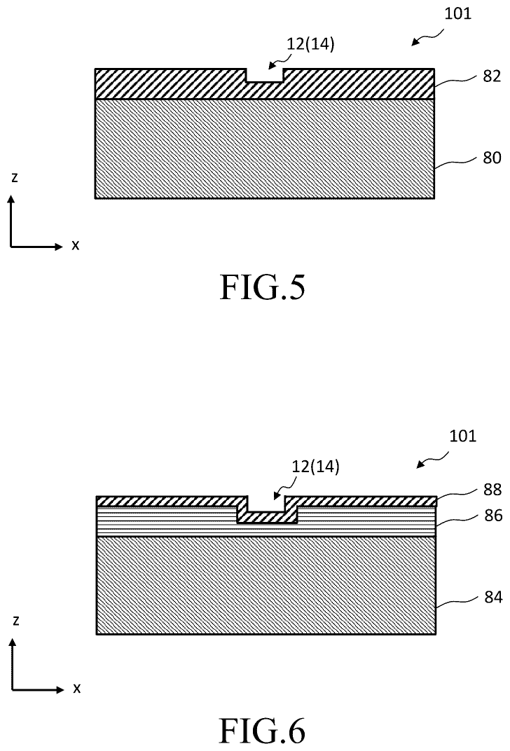

FIG. 5 is a cross-sectional view showing an example of the configuration of an alignment mark in Embodiment 1. In the example of FIG. 5, a case is shown in which an exposure mask is used as the target object 101. In the target object 101, as shown in FIG. 5, for example, a light shielding film 82 formed of chromium (Cr) or the like is formed on a glass substrate 80. Then, a recess is formed in the light shielding film 82, and the concave portion is used as the pattern linewidth of the alignment mark. Therefore, the surface of the concave portion and the surface of the convex portion become the same light shielding film 82. Thus, the small mark 14 serving as an alignment mark is formed with an uneven structure of the same material. Similarly, the large mark 12 is formed with an uneven structure of the same material. Then, a resist is applied to the target object 101 (mask) on which these marks are formed, and the target object 101 is transported into the writing apparatus 100 to perform mark measurement.

FIG. 6 is a cross-sectional view showing another example of the configuration of the alignment mark in Embodiment 1. In the example of FIG. 6, a case is shown in which an EUV exposure mask is used as the target object 101. In the target object 101, a multi-layer film 86 in which, for example, molybdenum (Mo) and silicon (Si) are stacked in multiple layers is formed on a low thermal expansion glass substrate 84. Then, a recess is formed in a part of the multi-layer film 86, and an absorber film 88 (anti-reflection film) containing, for example, Cr or tantalum (Ta) as a main component is formed on the multi-layer film 86 including the concave portion. Then, a concave portion of the absorber film 88 formed on the concave portion of the multi-layer film 86 is used as the pattern linewidth of the alignment mark. Therefore, the surface of the concave portion and the surface of the convex portion become the same absorber film 88. Thus, the small mark 14 serving as an alignment mark is formed with an uneven structure of the same material. Similarly, the large mark 12 is formed with an uneven structure of the same material. Then, a resist is applied to the target object 101 (mask) on which these marks are formed, and the target object 101 is transported into the writing apparatus 100 to perform mark measurement.

In FIGS. 5 and 6 described above, an example is given in which a mark portion is concave, and the following processing is also explained as concave type signal processing accordingly. However, there may be a case where the mark portion is convex. In this case, the series of processes are the same, except that the output signal is of a convex type.

Conventionally, an alignment mark on the target object 101 is searched for with an electron beam, and the position of the alignment mark is measured with the electron beam. However, in the case of a mark having an uneven structure of the same material, the difference in electron yield when the mark is scanned with an electron beam is small, making it difficult to obtain contrast. As a result, there has been a problem that the S/N ratio is small and it is difficult to find the alignment mark on the target object 101. In response to this, it is considered to increase the exposure intensity of the electron beam in order to obtain contrast. However, this method has a problem in that the resist is irradiated with a high exposure intensity of electron beam over a wide range, causing the resist to scatter and contaminate the inside of the chamber. Therefore, in Embodiment 1, first, an alignment mark is searched for in a wide region on the surface of the target object 101 using laser light that does not cause resist scattering or causes negligible resist scattering, and its center position is measured. Then, after the center position is specified, the center position of the alignment mark is measured by an electron beam with higher accuracy than the measured value using laser light. Hereinafter, a specific operation will be described.

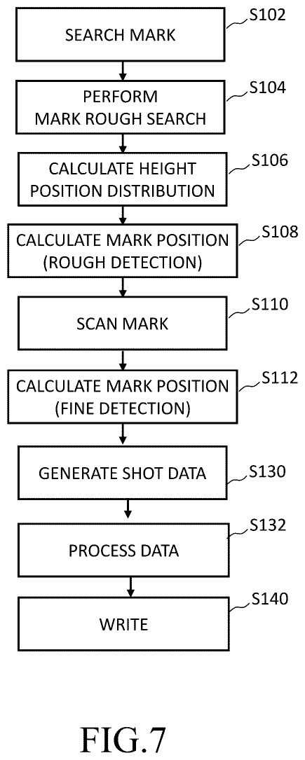

FIG. 7 is a flowchart showing an example of main steps of a writing method according to Embodiment 1. In FIG. 7, in the writing method according to Embodiment 1, respective steps such as a mark search step (S102), a mark rough search step (S104), a height position distribution calculation step (S106), a mark position calculation (rough detection) step (S108), a mark scan step (S110), a mark position calculation (fine detection) step (S112), a shot data generation step (S130), a data processing step (S132), and a writing step (S140) are executed.

Depending on the mask position accuracy required for writing, the process may proceed from the mark position calculation (rough detection) step (S108) to the shot data generation step (S130).

In the mark search step (S102), the large mark 12 is searched for in a wide region on the target object 101 using the z sensor 220. The position of the alignment mark region 10 on the target object 101 is determined by design. However, the relative positional relationship between the target object 101 that has been carried into the writing chamber 103 and placed on the XY stage 105 and the XY stage 105 does not necessarily match the designed positional relationship. For example, the target object 101 may be misaligned. For this reason, the large mark 12 may not be present at the position where the large mark 12 should be according to the design. Therefore, the actual large mark 12 is searched for based on the designed position of the large mark 12. Specifically, the XY stage 105 is moved to a designed position where the large mark 12 is irradiated with the laser light from the z sensor 220. Using this position as a reference, the XY stage 105 is moved by a distance, at which laser light is sufficiently emitted, from the reference position, for example, at a predetermined pitch in the +x direction from a position away in the −x direction. In this manner, the height position of the target object 101 is measured at a plurality of measurement positions. Therefore, it is possible to relatively measure height positions at a plurality of measurement positions in the x direction on the target object surface. The measured height position information is output to the control calculator 110. In addition to moving the XY stage 105 to the designed position where the large mark 12 is irradiated, the light projector 222 and the light receiver 224 may be moved in conjunction with each other to irradiate the surface of the target object 101 with laser light, or the irradiation direction of the laser light from the light projector 222 may be changed and the receiving position of the light receiver 224 may be in conjunction with the change to irradiate the surface of the target object 101 with the laser light.

The height position distribution calculation unit 50 receives the measured height position information and calculates a height position distribution. Then, the mark specifying unit 52 searches for a position where the height position is lower than the surrounding region, and specifies the large mark 12. The height position distribution obtained from the z sensor 220 will be described in detail later.

In the mark rough search step (S104), while moving the target object 101 placed on the XY stage 105, the height position distribution of the surface of the target object 101, which is obtained by performing a scan with laser light so as to cross, for example, the specified large mark 12 (uneven mark), is measured by using the z sensor 220.

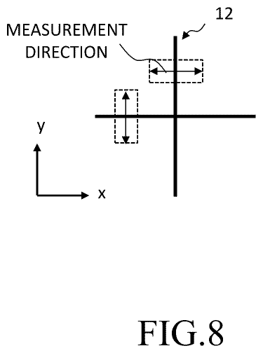

FIG. 8 is a diagram for explaining a method of performing a mark rough search in Embodiment 1. As shown in FIG. 8, the large mark 12 is formed by making a line pattern extending in the x direction and a line pattern extending in the y direction cross each other in a cross shape. Therefore, the position of the line pattern of the large mark 12 is measured on the paper surface of FIG. 8. With a direction perpendicular to a direction in which the line pattern extends as a measurement direction, a scan is performed in the measurement direction. For example, a scan is performed by a distance twice the beam diameter of the laser light. In the example of FIG. 8, a case where a line pattern extending in the y direction is scanned in the x direction and a case where a line pattern extending in the x direction is scanned in the y direction are shown. Specifically, the irradiation position of the laser light from the z sensor 220 on the surface of the target object 101 is sequentially moved to a plurality of measurement positions by moving the XY stage 105. When there is a lot of noise signal due to location dependency or the like, the noise components are averaged or cancelled out by repeatedly performing a calculation and averaging at a plurality of locations in a non-measurement direction perpendicular to the measurement direction. For example, in the measurement of the line pattern extending in the y direction described above, scan and measurement in the x direction are performed, and then stepping in the y direction occurs and the step for scan and measurement in the x direction is repeated.

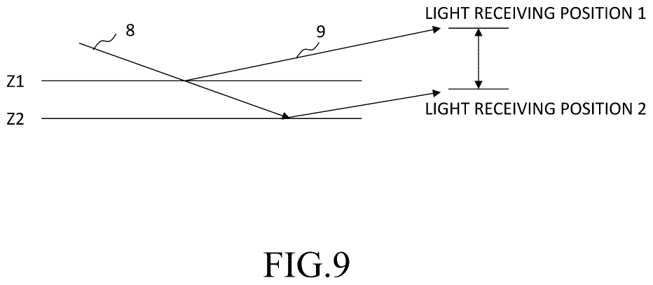

FIG. 9 is a diagram for explaining the measurement principle of the z sensor in Embodiment 1. The light receiving position changes between a light receiving position 1, which is the center of gravity position of reflected light 9 where the reflected light 9 of laser light 8 reflected at height Z1 is received by a light receiver, and a light receiving position 2, which is the center of gravity position of the reflected light 9 where the reflected light 9 of the same laser light 8 reflected at height 22 is received by the light receiver. The height position on the surface of the target object 101 can be calculated by multiplying the light receiving position by a height conversion coefficient.

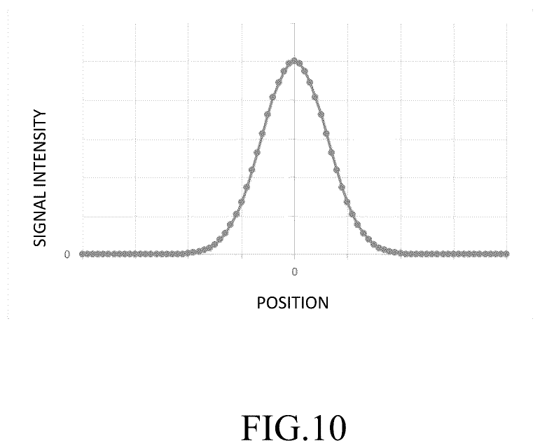

FIG. 10 is a diagram showing an example of the intensity distribution of laser light used in the z sensor in Embodiment 1. As shown in FIG. 10, the laser light used in the z sensor 220 in Embodiment 1 has a light intensity distribution of a normal distribution. In other words, the intensity of the laser light increases toward the center of the beam and decreases radially outward. As the laser light, for example, visible light is preferably used.

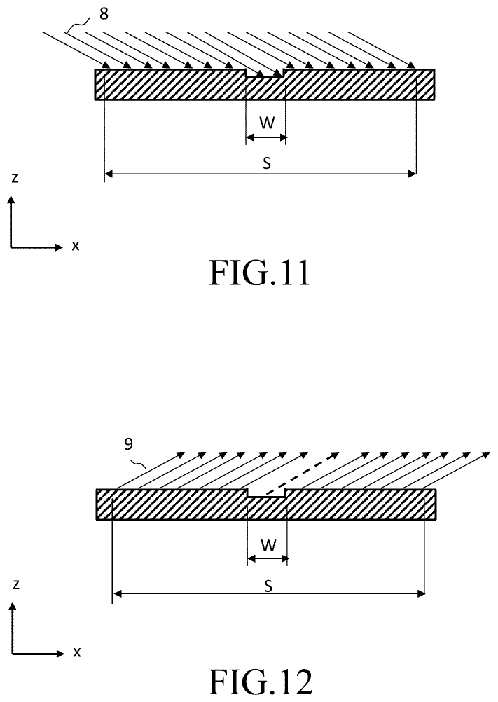

FIG. 11 is a cross-sectional view showing an example of a state of emitted light when the alignment mark is scanned by the z sensor in Embodiment 1.

FIG. 12 is a cross-sectional view showing an example of a state of reflected light when the alignment mark is scanned by the z sensor in Embodiment 1.

As the pattern linewidths of the large mark 12 and the small mark 14 become smaller, the laser light 8 used in the z sensor 220 has a diameter larger than the width (pattern linewidth) of the large mark 12 (uneven mark). The laser light 8 having a beam diameter of, for example, 10 μm to 300 μm is emitted to the surface of the target object 101. The laser light 8 having a beam diameter of, for example, 200 μm is emitted to the surface of the target object 101. The light projector 222 of the z sensor 220 makes the laser light 8 obliquely incident on the surface of the target object 101. Therefore, as shown in FIG. 11, a wide region with a width S including the large mark 12 with a pattern linewidth W is irradiated with the laser light 8 at the same time. Then, the light receiver 224 receives the reflected light 9 from the target object 101 due to the emission of the laser light 8. At this time, the light receiver 224 simultaneously receives the reflected light 9 from the wide region with the width S including the large mark 12 with the pattern linewidth W, as shown in FIG. 12. As shown in FIG. 12, the reflected light 9 includes some beams (dotted line) having height information of the bottom surface of the concave portion of the large mark 12 (uneven mark). Then, the light receiver 224 outputs height information of the surface of the target object 101.

In the height position distribution calculation step (S106), the height position distribution calculation unit 54 receives the measured height position information and calculates a height position distribution. The height position distribution of the surface of the target object 101 is obtained by scanning the large mark 12 (uneven mark) with the laser light 8 so as to cross each other as shown in FIG. 8. Through the mark rough search step (S104), the position of the line pattern is measured at each of the top, bottom, left, and right positions of the large mark 12 on the paper surface of FIG. 8. At this time, since the measurement is repeated in multiple stages while shifting the position in a direction in which the line pattern extends (non-measurement direction), the height position information of the multiple stages is output from the light receiver 224. Therefore, the height position distribution calculation unit 50 averages the measurement results measured in multiple stages in the non-measurement direction. As a result, it is possible to reduce the effect of differences in mark locations and noise during measurement.

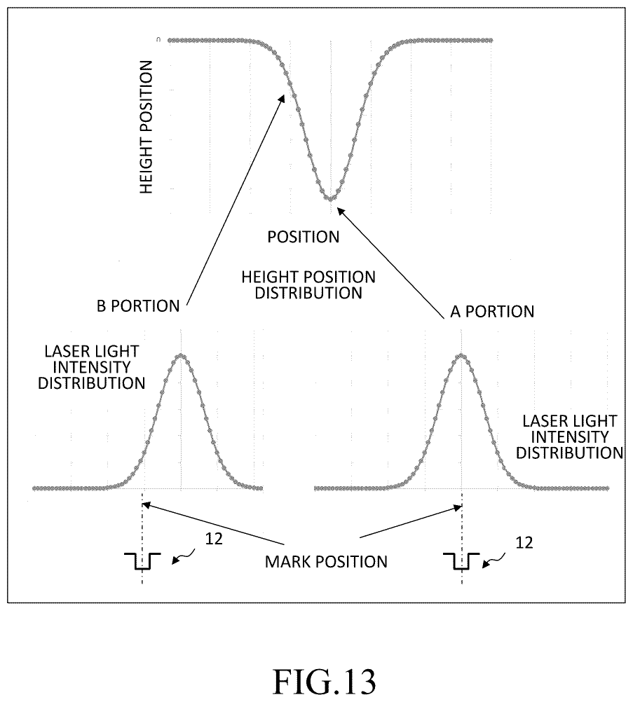

FIG. 13 is a diagram showing an example of the height position distribution of an uneven mark in Embodiment 1. In FIG. 13, the vertical axis indicates a height position, and the horizontal axis indicates a position (for example, a position in the x direction) on a target object. In Embodiment 1, the laser light 8 used in the z sensor 220 has a light intensity distribution of a normal distribution. If the laser light 8 has a light intensity distribution, the reflected light 9 also has a light intensity distribution corresponding to the light intensity of the original laser light 8. The height position is calculated by multiplying the light receiving position, which is the center of gravity position of the received reflected light 9, by the height conversion coefficient. The center of gravity position of the reflected light 9 is influenced by the light intensity at each light receiving position on the light receiving surface of the light receiver 224. Therefore, the change in the center of gravity position can be made larger when the height information of the bottom of the concave surface is acquired from a portion with a high light intensity than when the height information is acquired from a portion with a low light intensity. As a result, as shown in FIG. 13, when the large mark 12 with the pattern linewidth W is located within the beam diameter of the laser light 8, the height position changes depending on the position in the light intensity distribution where the large mark 12 with the pattern linewidth W is irradiated. As shown in FIG. 13, at height position A, a case is shown in which the large mark 12 is irradiated at the peak position of the light intensity (maximum value of the light intensity) of the laser light 8. At height position B, a case is shown in which the large mark 12 is irradiated at a light intensity position of, for example, about 20% of the peak position of the light intensity (maximum value of the light intensity) of the laser light 8. As shown in FIG. 13, the greater the light intensity at which the large mark 12 is irradiated, the greater the change in the height position of the concave surface compared to the height position of the convex surface. If the light intensity distribution of the laser light 8 is a normal distribution, when the large mark 12 is irradiated at the peak position of the normal distribution, the height position of the concave surface is output from the light receiver 224 as the lowest height position. Therefore, as shown in FIG. 13, the height position distribution of the surface of the target object 101 has a portion that changes continuously in the same direction over a range larger than the width of the large mark 12 (uneven mark), which is caused by the relative positional relationship between the light intensity distribution and the large mark 12 (uneven mark). On the left side of the peak position of the height position distribution, the height position changes continuously in a direction decreasing from the height position of the convex surface toward the peak position. Conversely, on the right side of the peak position of the height position distribution, the height position changes continuously in a direction increasing from the peak position toward the height position of the convex surface.

The height position distribution described above is calculated for each of the top, bottom, left, and right positions of the large mark 12.

In the mark position calculation (rough detection) step (S108), the mark position calculation unit 56 receives the calculated height position distribution at each of the top, bottom, left, and right positions of the large mark 12 (uneven mark) as height information of the surface of the target object 101. Then, the mark position calculation unit 56 calculates the position of the large mark 12 (uneven mark) using the height position distribution of the surface of the target object 101. Specifically, the calculation is performed as follows.

The mark position calculation unit 56 calculates the peak position of a normal distribution, which is obtained by approximating the height position distribution of the surface of the target object 101 using a density function of the normal distribution (hereinafter, referred to as a normal distribution function), as the position of the large mark 12 (uneven mark).

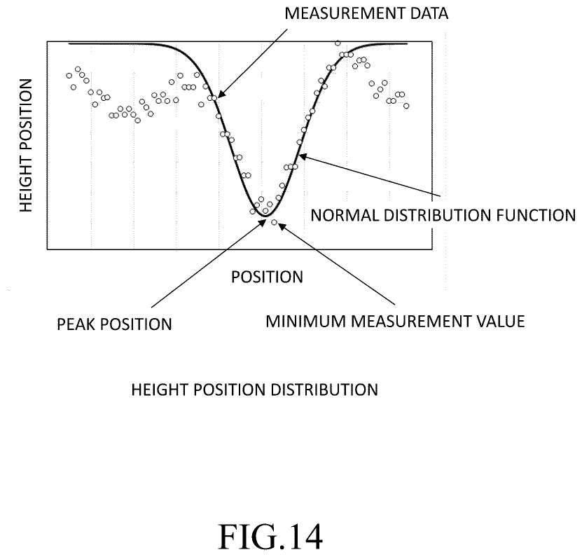

FIG. 14 is a diagram showing an example of the height position distribution in Embodiment 1. In FIG. 14, the vertical axis indicates a height position, and the horizontal axis indicates a position. In FIG. 14, measurement data at a plurality of measurement positions in the scanning direction is plotted. By approximating the measurement data at a plurality of measurement positions in the scanning direction with a normal distribution function, the peak position of the approximation line is calculated as the position of the large mark 12 (uneven mark).

Alternatively, the mark position calculation unit 56 may preferably calculate the center of gravity position of the height position distribution of the surface of the target object 101 and calculate the center of gravity position as the position of the large mark 12 (uneven mark). The center of gravity position g can be calculated using the coordinates mi and height position hi of the measurement data by the following Expression (1). i indicates an index.

$$g = \sum ( mi \cdot hi ) / \sum hi \qquad ( 1 )$$

Alternatively, the mark position calculation unit 56 may preferably calculate the position of the minimum height measurement value in the height position distribution of the surface of the target object 101 as the position of the large mark 12 (uneven mark). Among the pieces of measurement data at the plurality of measurement positions shown in FIG. 14, the minimum height measurement value is calculated as the position of the large mark 12 (uneven mark).

Alternatively, when the mark portion is convex, the signal direction is convex, so that it is preferable to calculate the position of the maximum height measurement value as the position of the large mark 12 (uneven mark).

Whichever method is used, the error of the position of the large mark 12 (uneven mark) obtained can be kept within the allowable range.

Then, the mark position calculation unit 56 can calculate the x position (x coordinate) of the center of the large mark 12 by calculating the average value of the x position measured at a position above the large mark 12 and the x position measured at a position below the large mark 12. Similarly, it is possible to calculate the y position (y coordinate) of the center of the large mark 12 by calculating the average value of the y position measured at a position on the right side of the large mark 12 and the y position measured at a position on the left side of the large mark 12.

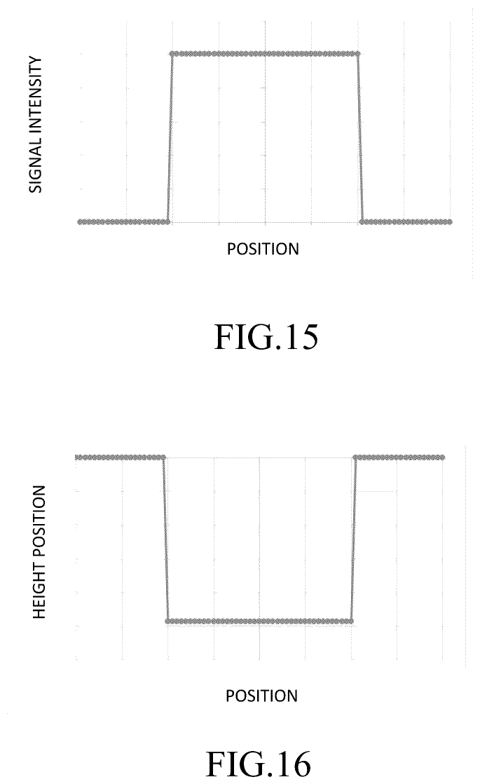

FIG. 15 is a diagram showing an example of the intensity distribution of laser light in a comparative example of Embodiment 1. The comparative example in FIG. 15 shows laser light having a uniform light intensity within the beam diameter.

FIG. 16 is a diagram showing an example of the height position distribution of an uneven mark in a comparative example of Embodiment 1. When an uneven mark is scanned with laser light having a uniform light intensity within the beam diameter, no matter where within the beam diameter the large mark 12 with the pattern linewidth W is irradiated with the laser light, the center of gravity position of the reflected light remains constant within the range of the beam diameter as shown in FIG. 16 and does not change. For this reason, it is difficult to find the peak position with high accuracy. On the other hand, in Embodiment 1, it is possible to find the peak position with high accuracy by using the laser light having a light intensity distribution of a normal distribution.

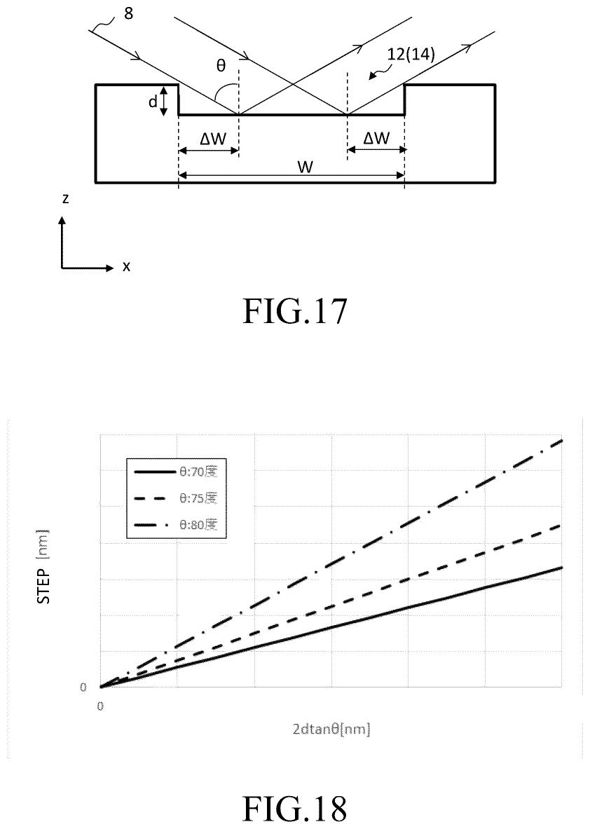

FIG. 17 is a diagram for explaining the relationship among the incidence angle of laser light, the step of an uneven mark, and the width of the uneven mark in Embodiment 1. Due to the step structure of the uneven mark, a region where the laser light does not reach the bottom of the mark occurs in a range of a distance ΔW from the edge of the concave portion. The distance W can be defined by the following Expression (2) using the incidence angle θ of the laser light and the step d of the uneven mark.

$$Δ W = tan θ \cdot d \qquad ( 2 )$$

The regions where the laser light does not reach are on the left and right sides. Therefore, the condition for being able to acquire a signal at the bottom of the mark is that the width W of the uneven mark should be greater than twice the distance ΔW.

Therefore, the relationship among the incidence angle θ of the laser light, the step d of the uneven mark, and the width W of the uneven mark needs to satisfy the following Expression (3).

$$W > 2 d \cdot tan θ \qquad ( 3 )$$

FIG. 18 is a diagram showing the relationship between the step of an uneven mark and 2d·tan θ in Embodiment 1. In FIG. 18, the vertical axis indicates the step d of the uneven mark. The horizontal axis indicates 2d·tan θ. It can be seen that the larger the incidence angle θ of the laser light, the larger the width W of the uneven mark should be in order to acquire a signal at the bottom of the mark with the same step d.

In the above example, a case where the center position of the large mark 12 is measured using the z sensor 220 has been described, but the invention is not limited thereto. A target mark in the mark rough search step (S104), the height position distribution calculation step (S106), and the mark position calculation (rough detection) step (S108) may be the small mark 14.

As described above, the center position of the alignment mark (here, the large mark 12) can be measured using the z sensor 220. Then, the center position of the alignment mark is measured with high accuracy using an electron beam. Specifically, the position of the small mark 14 (uneven mark) is measured by scanning the small mark 14 (uneven mark) with the electron beam in a state in which the XY stage 105 is moved to a position where the small mark 14 (uneven mark) can be irradiated with the electron beam using the information on the position of the uneven mark searched for in the mark position calculation (rough detection) step (S108).

In the mark scan step (S110), first, the XY stage 105 is moved to a position where the small mark 14 (uneven mark) can be irradiated with the electron beam using the information on the position of the uneven mark searched for in the mark position calculation (rough detection) step (S108). The relative positions of the large mark 12 and the small mark 14 are determined in advance. Therefore, if the center position of the large mark 12 is determined by the z sensor 220, the designed center position of the small mark 14 is determined. Then, the small mark 14 (uneven mark) is scanned by deflecting the electron beam with the deflector 209 in a state in which the XY stage 105 is moved to a position where the small mark 14 (uneven mark) can be irradiated with the electron beam. For example, similarly to scanning the large mark 12 as described with reference to FIG. 8, the top, bottom, left, and right positions of the small mark 14 are scanned. However, it is sufficient herein to perform a scan in the range of, for example, 20 to 30 μm in the measurement direction. In this manner, the range scanned with the electron beam can be significantly reduced compared to the conventional methods.

As the electron beam used for such scanning, it is preferable to use one beam selected from the multiple beams 20 or a plurality of beams including beams adjacent to one selected beam. The beam selection may be performed by setting a beam or a plurality of beams selected by a blanking aperture mechanism 204 to ON beam and setting the remaining beam array to beam OFF.

The secondary electrons emitted from the target object 101 when the small mark 14 (uneven mark) is scanned are detected by the detector 226. The detection data is converted from analog data to digital data by the detector 226, amplified, and output from the detector 226 to the control calculator 110.

In the mark position calculation (fine detection) step (S112), the mark position calculation unit 58 calculates the center position of the small mark 14 (uneven mark) using secondary electron image data at the top, bottom, left, and right positions of the small mark 14 due to the secondary electrons obtained in the mark scan step (S110). In other words, the writing mechanism 150 calculates the position of the small mark 14 (uneven mark) by scanning the small mark 14 (uneven mark) with an electron beam in a range narrower than the scanning range of the laser light from the z sensor 220 using the information on the calculated position of the large mark 12 (uneven mark). For example, the positions of both edges that configure the top, bottom, left, and right pattern linewidths of the small mark 14 in the secondary electron image can be measured, and the average value of the center positions of the top and bottom pattern linewidths and the average value of the center positions of the left and right pattern linewidths can be calculated as the x and y coordinates of the small mark 14, respectively.

In Embodiment 1, it is possible to reduce a region scanned with an electron beam by performing a fine search using an electron beam after a rough search using laser light that does not cause resist scattering or causes negligible resist scattering. Since the approximate position of the small mark 14 is already known by the rough search, the uneven structure of the small mark 14 can be grasped by the electron beam even if the uneven mark is formed of the same material. Therefore, the scattering of the resist can be suppressed or reduced. In addition, even when the incident exposure intensity (dose) of the electron beam is increased, the scattering of the resist can be reduced.

As described above, it is possible to calculate the highly accurate x, y coordinates of the small mark 14 serving as an alignment mark.

In addition, in each of the above-described steps from the mark search step (S102) to the mark position calculation (fine detection) step (S112), the same mark may be used between the large mark 12 and the small mark 14. Alternatively, a mark that is opposite to that described above may be used between the large mark 12 and the small mark 14. It is sufficient to use a mark in each step depending on the required accuracy and the type and number of marks configured.

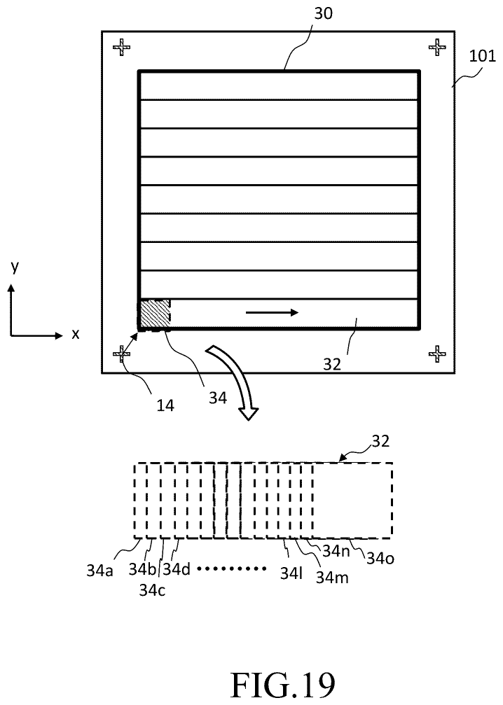

FIG. 19 is a conceptual diagram for explaining an example of a writing operation in Embodiment 1. As shown in FIG. 19, the position of the writing region 30 (bold line) of the target object 101 is defined with the position of, for example, the small mark 14 that becomes the obtained alignment mark as a reference.

The writing region 30 (bold line) is virtually divided into a plurality of rectangular striped regions 32 with a predetermined width in the y direction, for example. In the example of FIG. 19, a case is shown in which the writing region 30 of the target object 101 is divided into a plurality of striped regions 32, for example, in the y direction, with the substantially the same width as the size of the designed irradiation region 34 (writing field) that can be irradiated with one-time multiple beams 20. The size of the designed irradiation region 34 of the multiple beams 20 in the x direction can be defined as the number of beams in the x direction×the pitch between beams in the x direction. The size of the rectangular irradiation region 34 in the y direction can be defined as the number of beams in the y direction×the pitch between beams in the y direction.

First, the XY stage 105 is moved to make an adjustment so that the irradiation region 34 of the multiple beams 20 is located at the left end of the first striped region 32 or further to the left, and writing in the first striped region 32 is performed. When writing the first striped region 32, the XY stage 105 is moved, for example, in the −x direction, so that the writing proceeds relatively in the x direction. The XY stage 105 is continuously moved, for example, at a constant speed. After the writing in the first striped region 32 ends, the stage position is moved in the −y direction by the width of the striped region 32.

Then, an adjustment is made so that the irradiation region 34 of the multiple beams 20 is located at the left end of the second striped region 32 or further to the left, and the XY stage 105 is moved, for example, in the −x direction so that the writing proceeds relatively in the x direction. In this manner, the writing in the second striped region 32 is performed.

In addition, although a case where the writing in each striped region 32 proceeds in the same direction is shown in the example of FIG. 19, the invention is not limited thereto. For example, for the striped region 32 where writing is to be performed next to the striped region 32 where writing has been performed in the x direction, the writing may be performed in the −x direction by moving the XY stage 105, for example, in the x direction. By performing writing while alternately changing the direction in this manner, the stage movement time can be shortened, and the writing time can be shortened. In one shot, by the multiple beams 20 formed by passing through each hole 22 of the shaping aperture array substrate 203, a plurality of shot patterns, up to the same number as each hole 22, are formed at a time.

In addition, although a case where the stage movement for writing in each striped region is performed once at a time is shown in the example of FIG. 19, the invention is not limited thereto. It is also preferable to perform multi-writing so that the stage moves multiple times on the same position. In this case, for example, it is preferable to perform multi-writing while shifting in the y direction by a shift amount of 1/n of the width of the striped region.

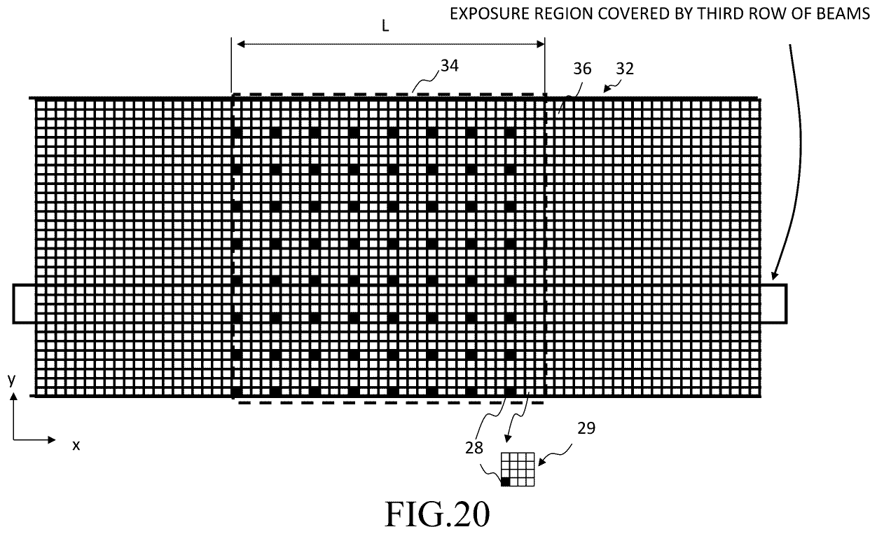

FIG. 20 is a diagram showing an example of a multi-beam irradiation region and a writing target pixel in Embodiment 1. In FIG. 20, the striped region 32 is divided into a plurality of mesh regions with the beam size of the multiple beams 20 and a mesh shape, for example. Each of such mesh regions is a writing target pixel 36 (unit irradiation region, irradiation position, or writing position). The size of the writing target pixel 36 is not limited to the beam size, and may be any size regardless of the beam size. For example, the size of the writing target pixel 36 may be 1/n (n is an integer of 1 or more) of the beam size. The example in FIG. 20 shows a case where the writing region of the target object 101 is divided into a plurality of striped regions 32, for example, in the y direction, with substantially the same width as the size of the irradiation region 34 (writing field) that can be irradiated with one-time multiple beams 20. The size of the rectangular irradiation region 34 in the x direction can be defined as the number of beams in the x direction x the pitch between beams in the x direction. The size of the rectangular irradiation region 34 in the y direction can be defined as the number of beams in the y direction x the pitch between beams in the y direction. In the example of FIG. 20, for example, 512×512 columns of multiple beams are abbreviated to 8×8 columns of multiple beams. Then, in the irradiation region 34, a plurality of pixels 28 (beam writing positions) that can be irradiated with one shot of the multiple beams 20 are shown. The pitch between the pixels 28 adjacent to each other is the pitch between the multiple beams. A rectangular region surrounded with the size of the beam pitch in the x and y directions is one sub-irradiation region 29 (pitch cell). In the example of FIG. 20, a case is shown in which each sub-irradiation region 29 is formed by, for example, 4×4 pixels.

In the shot data generation step (S130), first, the shot data generation unit 70 generates shot data for each pixel 36. Specifically, the shot data generation unit 70 operates as follows. First, the shot data generation unit 70 reads writing data from the storage device 140, and calculates a pattern area density pρ′ within the pixel 36 for each pixel 36. Such processing is performed for each striped region 32, for example.

Then, the shot data generation unit 70 first virtually divides the writing region (here, for example, the striped region 32) into a plurality of proximity mesh regions (mesh regions for proximity effect correction calculation) in a mesh shape with a predetermined size. The size of the proximity mesh region is preferably set to about 1/10 of the range of influence of the proximity effect, for example, about 1 μm. Then, the shot data generation unit 70 reads out writing data from the storage device 140, and calculates, for each proximity mesh region, a pattern area density ρ′ of the pattern to be arranged within the proximity mesh region.

Then, the shot data generation unit 70 calculates a proximity effect correction dose coefficient Dp (x) (corrected exposure intensity) for correcting the proximity effect for each proximity mesh region. The unknown proximity effect correction dose coefficient Dp (x) can be defined by a threshold model for proximity effect correction that is similar to the conventional method and uses a back scattering coefficient η, a threshold exposure intensity Dth of the threshold model, a pattern area density ρ″, and a distribution function g (x).

Then, the shot data generation unit 70 calculates, for each pixel 36, an incident exposure intensity D (x) (dose) for irradiating the pixel 36. The incident exposure intensity D (x) may be calculated, for example, as a value obtained by multiplying a base doses of the beam Dbase by the proximity effect correction dose coefficient Dp and the pattern area density ρ′. The base doses of the beam Dbase can be defined as Dth/(½+η), for example. As described above, it is possible to obtain the incident exposure intensity D (x) for each pixel 36 with the proximity effect corrected, based on the layout of a plurality of figures defined in the writing data.

Then, the shot data generation unit 70 calculates the beam irradiation time for each pixel 36. The beam irradiation time for each pixel 36 can be calculated by dividing the incident exposure intensity D (x) of the pixel by the current density J.

In the data processing step (S132), the data processing unit 72 rearranges the obtained beam irradiation time data for each pixel 36 in the order of shots and stores the beam irradiation time data in the storage device 142. The transfer processing unit 74 transfers the beam irradiation time data to the deflection control circuit 130 in the order of shots.

In the writing step (S140), under the control of the writing control unit 76, the writing mechanism 150 writes a pattern on the target object 101 on the XY stage 105 using the multiple beams 20 while moving the XY stage 105. In the multi-beam writing, shot data of a region to be subjected to writing processing later is generated while performing writing processing. For example, shot data for the (k+2)-th striped region 32 is generated while performing writing in the k-th striped region 32. While repeating this operation, writing in all of the striped regions 32 is performed.

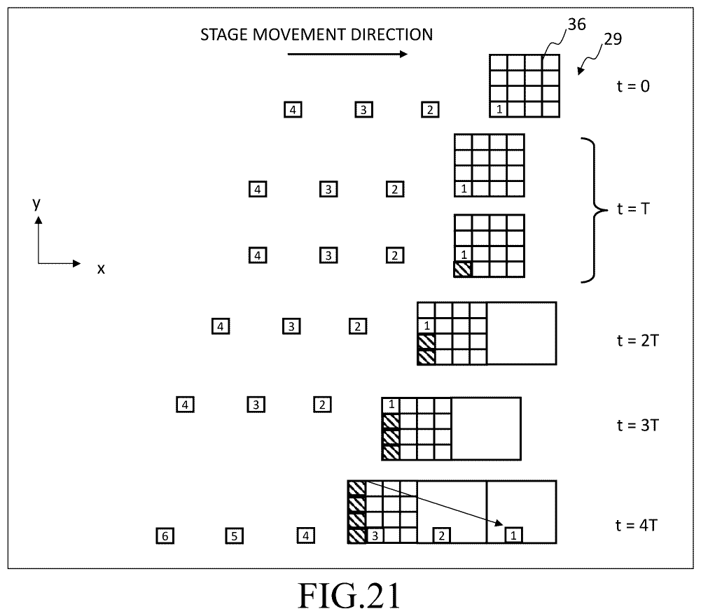

FIG. 21 is a diagram for explaining an example of a multi-beam writing operation in Embodiment 1. In the example of FIG. 21, a case is shown in which each sub-irradiation region 29 including one beam irradiation position of each of the multiple beams 20 and surrounded with the pitch between beams is written with four different beams. In addition, the example of FIG. 21 shows a writing operation in which the XY stage 105 moves continuously at a speed for movement by a distance of two beam pitches while writing a ¼ region (1/the number of beams used for irradiation) in each sub-irradiation region 29. In the example of FIG. 21, a case is shown in which each sub-irradiation region 29 is formed by, for example, 4×4 pixels.

In the writing operation shown in the example of FIG. 21, for example, four different pixels 36 within the same sub-irradiation region 29 are written (exposed) by performing four shots of the multiple beams 20 with a shot cycle T while shifting the irradiation position (pixel 36) sequentially by the deflector 209 during the movement of the XY stage 105 by a distance of two beam pitches in the x direction. The irradiation region 34 is caused to follow the movement of the XY stage 105 by collectively deflecting all of the multiple beams 20 with the deflector 208, so that the relative position of the irradiation region 34 with respect to the target object 101 does not shift due to the movement of the XY stage 105, while writing (exposing) the four pixels 36. In other words, tracking control is performed. When one tracking cycle ends, the tracking is reset to return to the previous tracking start position. In addition, since the writing of the first pixel column from the left of each sub-irradiation region 29 has been completed, in the next tracking cycle after tracking reset, the deflector 209 first performs deflection to match (shift) the writing position of the beam, which is different from the first pixel column, so as to write, for example, the second pixel column from the left that has not yet been written in each sub-irradiation region 29. By repeating this operation while writing the striped region 32, the position of the irradiation region 34 (34a to 34o) of the multiple beams 20 is sequentially moved as shown in the lower diagram of FIG. 19 to perform writing.

As described above, according to Embodiment 1, it is possible to detect a mark, which has a size smaller than the beam diameter of an emitted beam and has a surface formed of the same material, while suppressing the scattering of the resist.

### EMBODIMENT 2

In Embodiment 2, a configuration will be described in which the shape of the light intensity distribution of laser light used in the z sensor 220 is used to calculate the mark position. Hereinafter, the contents other than those specifically described are the same as those in Embodiment 1.

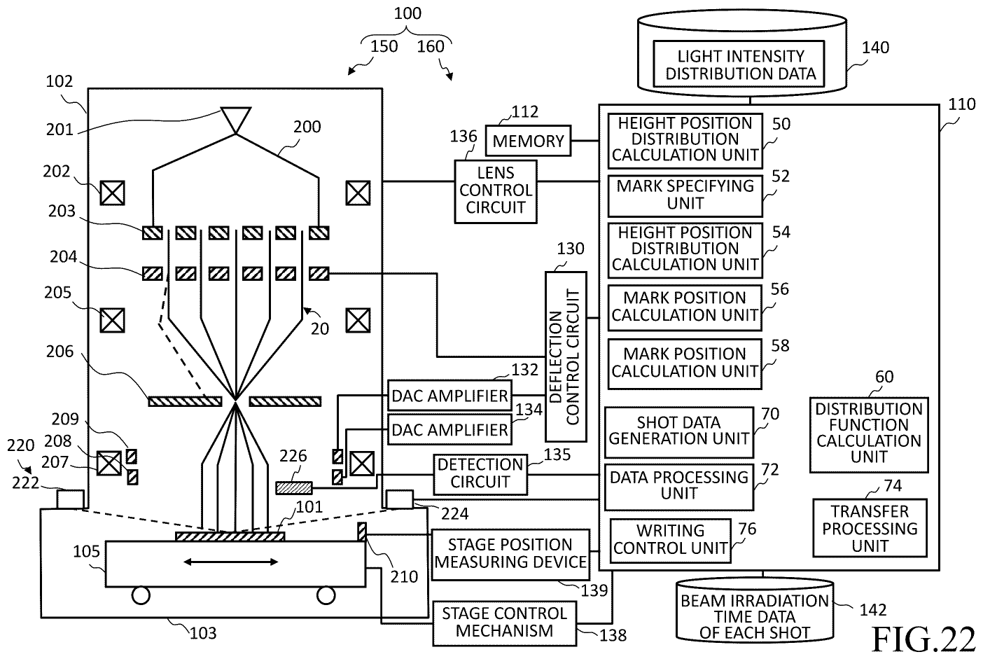

FIG. 22 is a conceptual diagram showing the configuration of a writing apparatus according to Embodiment 2. FIG. 22 is the same as FIG. 1 except that a distribution function calculation unit 60 is further arranged in the control calculator 110.

Therefore, each “˜unit”, such as the height position distribution calculation unit 50, the mark specifying unit 52, the height position distribution calculation unit 54, the mark position calculation unit 56, the mark position calculation unit 58, the distribution function calculation unit 60, the shot data generation unit 70, the data processing unit 72, the transfer processing unit 74, and the writing control unit 76, has a processing circuit. Examples of such a processing circuit include an electrical circuit, a computer, a processor, a circuit board, a quantum circuit, or a semiconductor device. For each “˜unit”, a common processing circuit (the same processing circuit) may be used or different processing circuits (separate processing circuits) may be used. Information input and output to and from the height position distribution calculation unit 50, the mark specifying unit 52, the height position distribution calculation unit 54, the mark position calculation unit 56, the mark position calculation unit 58, the distribution function calculation unit 60, the shot data generation unit 70, the data processing unit 72, the transfer processing unit 74, and the writing control unit 76 and information being calculated are stored in the memory 112 each time.

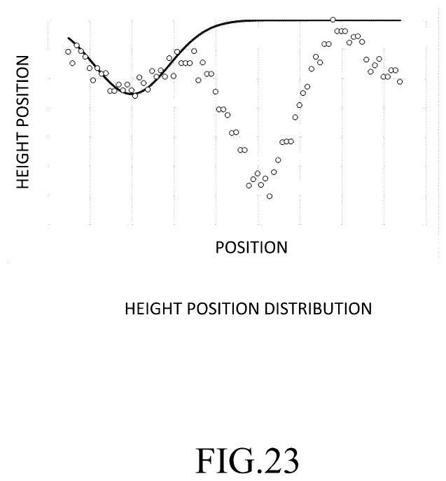

FIG. 23 is a diagram showing an example of the height position distribution in a comparative example of Embodiment 2. In FIG. 23, the vertical axis indicates a height position, and the horizontal axis indicates a position (for example, a position in the x direction) on a target object. In FIG. 23, similarly to FIG. 14, measurement data at a plurality of measurement positions in the scanning direction are plotted. When the surface of the target object 101 is an uneven surface with a step that is smaller than the step between the concave portion and the convex portion of the large mark 12 (uneven mark), an inflection point with a small deviation in the height direction may appear in the measurement data at a plurality of measurement positions, as shown in FIG. 23. In this state, when approximating the measurement data at a plurality of measurement positions in the scanning direction with a normal distribution function in the mark position calculation (rough detection) step (S108), it may be possible that a portion of the measurement data with a small step, which is different from the portion of the measurement data that should actually be approximated, is approximated by the normal distribution function, as shown in FIG. 23. In this case, the position of the large mark 12 (uneven mark) is incorrectly calculated.

On the other hand, measurement data indicating the height position of a concave portion of the large mark 12 (uneven mark) has a height position distribution that follows the light intensity distribution of the laser light of the z sensor 220. Therefore, in Embodiment 2, a function that follows the light intensity distribution of the laser light from the z sensor 220 is used as a normal distribution function used in the mark position calculation (rough detection) step (S108). Therefore, in Embodiment 2, the following operation is added to the operations in Embodiment 1.

First, information on the light intensity distribution of the laser light from the z sensor 220 is stored in advance in the storage device 140. The light intensity distribution of the laser light may be measured by the writing apparatus 100, or information previously measured externally may be input to the writing apparatus 100 and stored in the storage device 140.

In the distribution function creation step, the distribution function calculation unit 60 creates a function for a position along the light intensity distribution using the information on the light intensity distribution stored in the storage device 140. Specifically, a function that approximates the light intensity distribution is created. As the function for a position, for example, a normal distribution function is preferably used. When the light intensity distribution deviates from the normal distribution, a function that approximates the light intensity distribution with a polynomial may be created. The coefficients of the created function are stored in the storage device 140 or the like.

Then, each step in the flowchart shown in FIG. 7 is executed. The contents of each step in the flowchart shown in FIG. 7 are the same as those in Embodiment 1. However, in the mark position calculation (rough detection) step (S108), the mark position calculation unit 56 approximates the height position distribution of the surface of the target object 101 using the function for a position created along the light intensity distribution of the laser light of the z sensor 220. Then, the peak position of the distribution indicated by the function for a position obtained by approximation is calculated as the position of the large mark 12 (uneven mark). For example, the peak position of the distribution indicated by the normal distribution function obtained by approximation is calculated as the position of the large mark 12 (uneven mark). As a result, as described in FIG. 14, measurement data of a portion indicating the height position of the concave portion of the large mark 12 (uneven mark), among the pieces of measurement data of the plurality of measurement positions, can be approximated by the normal distribution function.

As described above, according to Embodiment 2, since the measurement data of the portion indicating the height position of the concave portion of the uneven mark can be approximated by the normal distribution function, it is possible to suppress erroneous calculation of the mark position.

The embodiments have been described above with reference to specific examples. However, the invention is not limited to these specific examples.

In addition, the description of parts that are not directly required for the description of the invention, such as the apparatus configuration or the control method, is omitted. However, the required apparatus configuration, control method, and the like can be appropriately selected and used. For example, although the description of the control unit configuration for controlling the writing apparatus 100 is omitted, it is needless to say that the required control unit configuration can be appropriately selected and used.

In addition, all position measurement apparatuses, charged particle beam writing apparatuses, and mark position measurement methods that include the elements of the invention and that can be appropriately modified by those skilled in the art are included in the scope of the invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A position measurement apparatus, comprising:
a movable stage, a target object having an uneven mark with a concave surface and a convex surface formed of a same material being placed on the stage;
a sensor having a light projector for making laser light obliquely incident on a surface of the target object and a light receiver for receiving reflected light from the target object due to emission of the laser light and outputting height information of the surface of the target object, the laser light having a predetermined light intensity distribution and having a diameter larger than a width of the uneven mark; and
a position calculation circuit configured to calculate a position of the uneven mark using a height position distribution of the surface of the target object as the height information of the surface of the target object, the height position distribution of the surface of the target object being obtained by performing a scan with the laser light so as to cross the uneven mark and generated by a relative positional relationship between the predetermined light intensity distribution and the uneven mark.

2. The apparatus according to claim 1,
wherein a part of the height position distribution of the surface of the target object has a portion changing continuously in a direction of the height position within a range larger than the width of the uneven mark.

3. The apparatus according to claim 1,
wherein the predetermined light intensity distribution is a normal distribution, and
the position calculation circuit calculates, as the position of the uneven mark, a peak position of a normal distribution obtained by approximating the height position distribution of the surface of the target object using a normal distribution function.

4. The apparatus according to claim 1,
wherein the position calculation circuit calculates a center of gravity position of the height position distribution of the surface of the target object as the position of the uneven mark.

5. The apparatus according to claim 1,
wherein the position calculation circuit calculates, as the position of the uneven mark, one of a position of a minimum height measurement value in the height position distribution of the surface of the target object and a position of a maximum height measurement value in the height position distribution of the surface of the target object.

6. The apparatus according to claim 1, further comprising:
a storage device configured to store information on a light intensity distribution of the laser light in advance; and
a distribution function creation circuit configured to create a function for a position along the light intensity distribution using the information on the light intensity distribution stored in the storage device,
wherein the position calculation circuit approximates the height position distribution of the surface of the target object using the function for a position created along the light intensity distribution.

7. The apparatus according to claim 6,
wherein a normal distribution function is used as the function for a position.

8. The apparatus according to claim 1,
wherein a relationship among an incidence angle θ of the laser light, a step d of the uneven mark, and a width W of the uneven mark is a relationship of W>2d·tan θ.

9. A charged particle beam writing apparatus, comprising:
a position measurement apparatus according to claim 1; and
a writing mechanism configured to write a pattern on the target object on the stage using a charged particle beam.

10. The apparatus according to claim 9,
wherein the writing mechanism calculates a position of the uneven mark by scanning the uneven mark with an electron beam in a range narrower than the scanning range of the laser light using information on a calculated position of the uneven mark.

11. The apparatus according to claim 10,
wherein the uneven mark has a large mark and a small mark,
the position measurement apparatus calculates a position of the large mark, and
the writing mechanism calculates a position of the small mark.

12. A mark position measurement method, comprising:
searching for a position of an uneven mark on a surface of a target object placed on a stage and having the uneven mark with a concave surface and a convex surface formed of a same material by calculating the position of the uneven mark using a height position distribution of the surface of the target object as height information of the surface of the target object, the height position distribution of the surface of the target object being obtained by performing a scan with laser light so as to cross the uneven mark using a sensor having a light projector for making the laser light having a predetermined light intensity distribution and having a diameter larger than a width of the uneven mark obliquely incident on the surface of the target object and a light receiver for receiving reflected light from the target object due to emission of the laser light and outputting the height information of the surface of the target object while moving the target object and generated by a relative positional relationship between the predetermined light intensity distribution and the uneven mark; and
measuring the position of the uneven mark by scanning the uneven mark with an electron beam after moving the stage to a position where the uneven mark is irradiated with the electron beam using information on a searched position of the uneven mark.

13. The method according to claim 12,
wherein a part of the height position distribution of the surface of the target object has a portion changing continuously in a direction of the height position within a range larger than the width of the uneven mark.

14. The method according to claim 12,
wherein the predetermined light intensity distribution is a normal distribution, and
a peak position of a normal distribution obtained by approximating the height position distribution of the surface of the target object using a normal distribution function is calculated as the position of the uneven mark.

15. The method according to claim 12, further comprising:
calculating a center of gravity position of the height position distribution of the surface of the target object as the position of the uneven mark.

16. The method according to claim 12, further comprising:
calculating, as the position of the uneven mark, one of a position of a minimum height measurement value in the height position distribution of the surface of the target object and a position of a maximum height measurement value in the height position distribution of the surface of the target object.

17. The method according to claim 12, further comprising:
storing information on a light intensity distribution of the laser light in advance in a storage device;
creating a function for a position along the light intensity distribution using the information on the light intensity distribution stored in the storage device; and
approximating the height position distribution of the surface of the target object using the function for a position created along the light intensity distribution.

18. The method according to claim 17,
wherein a normal distribution function is used as the function for a position.

19. The method according to claim 12,
wherein a relationship among an incidence angle θ of the laser light, a step d of the uneven mark, and a width W of the uneven mark is a relationship of W>2d·tan θ.
